(19) United States
(12) Patent Application Publication
(10) Pub. No.: US 2010/0165335 A1
(43) Pub. Date: Jul. 1, 2010

(54) SYSTEMS AND METHODS FOR RECEIVING AND/OR ANALYZING INFORMATION ASSOCIATED WITH ELECTRO-MAGNETIC RADIATION

(75) Inventor: Guillermo J. Tearney, Cambridge, MA (US)

Correspondence Address: DORSEY & WHITNEY LLP;INTELLECTUAL PROPERTY DEPARTMENT, 250 PARK AVENUE, NEW YORK, NY, 10177, US

(73) Assignee: The General Hospital Corporation, Boston, MA (US)

(21) Appl. No.: 12/376,026

(22) PCT Filed: Jul. 31, 2007
(86) PCT No.: PCT/US2007/074873

§ 371 Date: Feb. 17, 2010

Related U.S. Application Data
(60) Provisional application No. 60/838,472, filed on Aug. 16, 2006.
(60) Provisional application No. 60/835,004, filed on Aug. 1, 2006.
(60) Provisional application No. 60/841,620, filed on Aug. 30, 2006.
(60) Provisional application No. 60/838,285, filed on Aug. 16, 2006.

(51) Int. Cl. G01J 3/44; H01L 31/0232

(52) U.S. Cl. 356/301; 250/227.24

(57) ABSTRACT

According to an exemplary embodiment, a system can be provided which can have at least one fiber arrangement and at least one receiving arrangement. The fiber arrangement may have optical transmitting characteristics, and may be configured to transmit there through at least one electromagnetic radiation and forward the at least one electromagnetic radiation to at least one sample. At least one portion of the fiber arrangement may be composed of or can include therein sapphire, diamond, clear graphite, Chalcogenide, borosilicate, zirconium fluoride, silver halide, a liquid core light guide, a gas core light guide, a hollow core waveguide, and/or a solid core photonic crystal fiber. The receiving arrangement may be configured to receive the electromagnetic radiation that is filtered and received from the sample. According to another exemplary embodiment, a method can be provided for obtaining information associated with the sample. For example, at least one first electromagnetic radiation can be forwarded to the sample via at least one optical fiber. At least one first characteristic of at least one portion of the optical fiber can be controlled so as to modify at least one second characteristic of at least one second electromagnetic radiation generated within the optical fiber. The second electromagnetic radiation can be associated with the first electromagnetic radiation.

### CROSS-REFERENCE TO RELATED APPLICATION(S)

This application is based upon and claims the benefit of priority from U.S. Patent Application Ser. No. 60/835,004, filed Aug. 1, 2006, U.S. Patent Application Ser. No. 60/838,472, filed Aug. 16, 2006, U.S. Patent Application Ser. No. 60/838,285, filed Aug. 16, 2006, and U.S. Patent Application Ser. No. 60/841,620, filed Aug. 30, 2006, the entire disclosures of which are incorporated herein by reference.

### FIELD OF THE INVENTION

Exemplary embodiments of the present invention relates to systems and methods for receiving and/or analyzing information associated with electromagnetic radiation, and more particularly to such systems and methods which can received and/or analyze such information based on signals propagated via at least one fiber arrangement.

### BACKGROUND INFORMATION

Raman scattering is known to be a vibrational photo-molecular interaction that provides detailed quantitative analysis of an illuminated sample by examining the light emerging with a wavelength (energy or frequency) different from that of the excitation. In a conventional configuration, a narrow-band light (generally from a laser source) incident upon the sample of interest is inelastically scattered, and the remitted light is collected (through appropriate optics and filters) and spectroscopically analyzed.

Raman spectroscopy is a sensitive and specific analytical procedure for diagnosing various diseases, including atherosclerosis and cancers and pre-cancers of various organs such as brain, breast, colon, bladder, prostate, and cervix, as described in E. B. Hanlon et al., “Prospects for In Vivo Raman Spectroscopy,” Physics in Medicine and Biology, Vol. 45(2), p. R1 (2000); and A. Mahadevan-Jansen et al., “Raman Spectroscopy for the Detection of Cancers and Precancers,” Journal of Biomedical Optics, Vol. 1(1), p. 31 (1996). However, in a number of cases, practical application has been limited due to certain significant limitations. These limitations include a spectral examination through optical fiber probes with diameters small enough to access remote tissues and organs, and competing optical signals from the sample of interest, both of which are related to background luminescence and contribute excessive amounts of noise to the signal of interest.

Catheters and endoscopes capable of delivering light to and from a sample are important for a practical application of Raman spectroscopy, e.g., in the field of medicine. In general, this can be accomplished using optical fibers. For example, low-OH fused silica core/fused silica clad fibers can be implemented for this purpose, as described in M. Shim et al., “Development of an In Vivo Raman Spectroscopic System for Diagnostic Applications,” J Raman Spectrosc, Vol. 28, p. 131 (1997). However, the use of such fibers may also be problematic. The material of the fiber is Raman active. As the excitation light travels down the core, a large fiber background signal (which can overlap the spectral fingerprint region of most materials) can be generated which propagates along this fiber. This background can be elastically scattered by the sample, and may reach the detector in the same or substantially similar manner as the signal of interest. Further, a portion of the excitation light can also be reflected from the sample, and may cause the same or similar effect in the fibers used for collection, as described in R. L. McCreery, “Raman Spectroscopy for Chemical Analysis, Chemical Analysis: A Series of Monographs on Analytical Chemistry and Its Applications,” John Wiley & Sons, Inc., Vol. 157, p. 420 (2000).

An intense luminescence generated in optical fibers transmitting laser light is a drawback in the remote Raman spectroscopy, including providing catheter access to internal organs. This detrimental background is associated with a shot noise (as described below) that can completely overwhelm Raman signals from the interrogated sample. This deficiency can generally be overcome by employing separate fibers for delivery of laser light to, and collecting the Raman-scattered light from the tissue, along with filtering at the distal end of the optical fiber probe. The delivery (or excitation) fiber is terminated with or registered to a short-wavelength pass shown in FIG. 1B or band-pass filter that transmits the laser light to the tissue while blocking luminescence generated in the fiber as shown in FIG. 1A. The collection fibers are preceded at the distal end by a long-wavelength pass as shown in FIG. 1B or notch filter that prevents elastically scattered laser light from entering the fiber and generating additional background, while still transmitting the Raman scattered light from the sample as shown in FIG. 1C. Such filters can be of the dielectric, holographic, or absorptive type.

While the above-described strategy has been used in the past, the majority of commercial Raman probes are very large and likely inapplicable for endoscopic or angioscopic applications. Visionex, Inc. developed Raman probes with a diameter of ˜1 mm, as described in M. Shim et al., “Study of Fiber-Optic Probes for in Vivo Medical Raman Spectroscopy,” Appl Spectrosc, Vol. 53(6), p. 619 (1999). An optical fiber probe has been described which is less than 3 mm in diameter, that has been used to obtain high-quality in vivo Raman spectra of arterial and breast tissue, as described in J. T. Motz et al., “Optical fiber probe for biomedical Raman spectroscopy,” Applied Optics, Vol. 43(3), p. 542 (2004).

With respect to the detection of the electromagnetic radiation, a signal of a given intensity is likely associated with a certain level of noise. Such noise can be referred to as “shot noise,” and its amplitude may be equal to or approximately the square root of the detected signal. Therefore, the background that is generated in the fibers and gathered by the detection system also contributes noise to the final signal of interest. It is possible that this noise may be greater in amplitude than the Raman signal from the sample, thus resulting in mostly useless data with SNR<1. Furthermore, any additional non-Raman luminescence generated in the sample can also contribute to the shot noise. This has generally prevented a successful application of an excitation with visible lasers for investigating the biological samples.

Another source of background luminescence (e.g., noise) in Raman spectroscopy measurements is provided in further optical processes (such as fluorescence) from the sample itself. One possible way to circumvent this drawback is to employ pulsed lasers and time-gated detection because Raman scattering likely takes place in timescales on the order of femtoseconds (fs=10⁻¹⁵ s), while the fluorescence occurs on the order of nanoseconds (ns=10⁻⁹ s) as shown in FIG. 3A. Therefore, if the remitted light is collected only from the time of arrival of the laser pulse at the sample until the start of fluorescence emission, the majority of this background signal can be avoided as shown in FIG. 4. This procedure has been exploited pursuant to the use of pulsed lasers, and has been used in open air geometries (i.e., without the use of optical fibers) for review of biological tissue, such as bone, as described in M. D. Morris et al., “Kerr-gated time-resolved Raman spectroscopy of equine cortical bone tissue,” Journal of Biomedical Optics, Vol. 10(1) (2005), and bladder and prostate, as described in M. C. H. Prieto et al., “Use of picosecond Kerr-gated Raman spectroscopy to suppress signals from both surface and deep layers in bladder and prostate tissue,” Journal of Biomedical Optics, Vol. 10(4), p. 044006 (2005).

A development of catheters and endoscopes capable of delivering light to and from a sample is important for practical applications of Raman spectroscopy such as, e.g., in the field of medicine. In general, this can be accomplished through the use of optical fibers. It is known that low-OH fused silica core/fused silica clad fibers can be used for this purpose, as described in M. Shim et al., “Development of an In Vivo Raman Spectroscopic System for Diagnostic Applications,” J Raman Spectrosc, Vol. 28, p. 131 (1997). However, the use of such fibers can also be problematic. The material of the fiber is likely itself Raman active, and as the excitation light travels down the core a large fiber background signal, which overlaps the spectral fingerprint region of most materials, may be generated and propagates down the fiber. This background can be elastically scattered by the sample, and generally reach the detector in the same manner as the signal of interest. Furthermore, a portion of the excitation light is further reflected from the sample, and can cause the same effect in the fibers used for collection, as described in R. L. McCreery, “Raman Spectroscopy for Chemical Analysis, Chemical Analysis: A Series of Monographs on Analytical Chemistry and Its Applications,” John Wiley & Sons, Inc., New York, Vol. 157, p. 420, (2000).

One of the fundamental properties of a detection of the electromagnetic radiation is that the signal of a given intensity is generally always associated with a certain level of noise. This is termed “shot noise,” and its amplitude is equal to the square root of the detected signal. Therefore, the background that is generated in the fibers, and gathered by the detection system also contributes noise to the final signal of interest. It is often the case that this noise may be greater in amplitude than the Raman signal from the sample, resulting in useless data with SNR<1. As discussed above, this is generally circumvented by the use of optical filters.

There is a need to overcome the deficiencies described herein above.

### SUMMARY OF THE INVENTION

To address and/or overcome the above-described problems and/or deficiencies, exemplary embodiments of systems and methods which can be used for receiving and/or analyzing information associated with electromagnetic radiation, e.g., based on signals propagated via at least one fiber arrangement.

Thus, according to an exemplary embodiment of the present invention, a system can be provided which can have at least one fiber arrangement and at least one receiving arrangement. The fiber arrangement may have optical transmitting characteristics, and may be configured to transmit there through at least one electromagnetic radiation and forward the at least one electromagnetic radiation to at least one sample. At least one portion of the fiber arrangement may be composed of or can include therein sapphire, diamond, clear graphite, Chalcogenide, borosilicate, zirconium fluoride, silver halide, a liquid core light guide, a gas core light guide, a hollow core waveguide, and/or a solid core photonic crystal fiber. The receiving arrangement may be configured to receive the electromagnetic radiation that is filtered and received from the sample.

The fiber arrangement can include therein at least one filtering arrangement. The fiber and filtering arrangements can be configured to transmit there through the electromagnetic radiation and forward the electromagnetic radiation to the sample. The receiving arrangement can include therein at least one further filtering arrangement which may be adapted to filtered the received electromagnetic radiation. The receiving arrangement can be the further fiber arrangement which may have optical transmitting characteristics. The received electromagnetic radiation can be a Raman radiation associated with the sample. A further arrangement can be provided which may be configured to house therein at least one portion of the fiber arrangement. The sample may be provided at least partially within an anatomical structure.

The receiving arrangement may include a fiber arrangement which can be composed of or include therein sapphire, diamond, clear graphite, Chalcogenide, borosilicate, zirconium fluoride, silver halide, a liquid core light guide, a gas core light guide, a hollow core waveguide, and/or a solid core photonic crystal fiber. The fiber arrangement can include at least one first fiber which may have at least one first filtering characteristic that filter the electromagnetic radiation. The receiving arrangement may be configured to receive the electromagnetic radiation that is filtered by the fiber and/or a second fiber which may have the second filtering characteristic that filter the electromagnetic radiation. The fiber arrangement and the receiving arrangement may be the same arrangements.

According to yet another exemplary embodiment of the present invention at least one further fiber arrangement can be provided which is configured to receive the electromagnetic radiation that is filtered and received from the sample. This further fiber arrangement may be composed of or includes therein sapphire, diamond, clear graphite, Chalcogenide, borosilicate, zirconium fluoride, silver halide, a liquid core light guide, a gas core light guide, a hollow core waveguide, and/or a solid core photonic crystal fiber. Further, the fiber arrangement may include therein at least one filtering arrangement, and the fiber and filtering arrangements may be are configured to transmit there through the electromagnetic radiation and forward the electromagnetic radiation to the sample. At least one filtering characteristic of the filtering arrangement can be provided by a fiber Bragg grating. The first fiber and/or the second fiber can be filtered based on the first filtering characteristic and/or the second filtering characteristic to prevent at least one portion of the electromagnetic radiation having particular wavelengths from being forwarded therein.

According to still another exemplary embodiment of the present invention, the electromagnetic radiation can have at least one characteristic so as to reduce and/or substantially eliminate a fluorescence from the sample. For example, the electromagnetic radiation may cause a stimulated depletion of the fluorescence from the sample. Further, the electromagnetic radiation may photobleach the fluorescence from the sample.

In yet another further exemplary embodiment of the present invention, a first optical fiber arrangement can be provided which may be configured to propagate therethrough at least one first electromagnetic radiation to the sample provided at least partially within an anatomical structure, and received at least one second electromagnetic radiation from the sample. At least one second arrangement can be provided which may be configured to collect first portions of the second electromagnetic radiation and exclude second portions of the second electromagnetic radiation as a function of time.

For example, the first portions can include inelastic scattering portions of the second electromagnetic radiation, and the second portions may include fluorescent portions of the second electromagnetic radiation. The second portions may further include a background electromagnetic radiation generated within the first arrangement. The second portions can further include an elastically-scattered electromagnetic radiation reflected within the first arrangement and/or from the sample. In addition, the first portions may include a first set of signals and a second set of signals. The first set can be received at the second arrangement at a time which is earlier than a time at which the second set is received at the second arrangement. The second arrangement may be further configured to determine information associated with at least one depth of the sample as a function of the first and second sets of the signals. The first arrangement may be configured to allow at least some of the wavelengths of the first electromagnetic radiation to propagate therethrough at approximately the same velocity. The anatomical structure may include a portion which has a coronary artery.

According to still another exemplary embodiment of the present invention, the second characteristic of the second electromagnetic radiation can be modulated. The second modulated electromagnetic radiation can be compared with at least one third electromagnetic radiation provided from the sample. Dissipation of heat from the portion of the optical fiber can be directed in a particular manner. The portion of the optical fiber can also be insulated, and/or may have a conductivity sufficient to change of the first characteristic throughout the optical fiber when applied at a discrete location.

Still another exemplary embodiment of system and method according to the present invention can be provided. For example, at least one fiber arrangement can be utilized (which has optical transmitting characteristics) that may include therein at least one filtering arrangement. The fiber arrangement and the filtering arrangement may be configured to transmit there through at least one electromagnetic radiation, and forward the at least one electromagnetic radiation to at least one sample. At least one receiving arrangement may be provided that is configured to receive the electromagnetic radiation that is filtered and received from the sample. At least one portion of the fiber arrangement may be composed of or includes therein sapphire, diamond, clear graphite, Chalcogenide, borosilicate, zirconium fluoride, silver halide, a liquid core light guide, a gas core light guide, a hollow core waveguide, and/or a solid core photonic crystal fiber.

According to another exemplary embodiment, a method can be provided for obtaining information associated with the sample. For example, at least one first electromagnetic radiation can be forwarded to the sample via at least one optical fiber. At least one first characteristic of at least one portion of the optical fiber can be controlled so as to modify at least one second characteristic of at least one second electromagnetic radiation generated within the optical fiber. The second electromagnetic radiation can be associated with the first electromagnetic radiation.

The controlling procedure can include an increase of energy of one or more molecules that reside in the portion of the optical fiber. The first characteristic can include temperature. Further, the controlling procedure may includes an excitation of an optical illumination of the portion of the optical fiber, and/or a generation of an electrical field at approximately the portion of the optical fiber. In addition, it is possible to reduce or remove a background radiation associated with the second electromagnetic radiation. Further, it is possible to modulate the second characteristic of the second electromagnetic radiation. It is also possible to compare the second modulated electromagnetic radiation with at least one third electromagnetic radiation provided from the sample. In addition, a dissipation of heat can be directed from the portion of the optical fiber in a particular manner. The portion of the optical fiber may be insulated, and/or can have a conductivity sufficient to effectuate a change of the first characteristic throughout the optical fiber when applied at a discrete location.

According to still another exemplary embodiment of the present invention, a system can be provided for obtaining information associated with at least one sample. For example, at least one first radiation generating arrangement can be provided which may be configured to forward at least one first electromagnetic radiation to the sample via at least one optical fiber. At least one second arrangement may also be provided which may be configured to control at least one first characteristic of at least one portion of the optical fiber so as to modify at least one second characteristic of at least one second electromagnetic radiation generated within the optical fiber. The second electromagnetic radiation may be associated with the first electromagnetic radiation.

According to a still further exemplary embodiment of the present invention, an arrangement can be provided for obtaining information associated with at least one sample. The arrangement can include a first module, which when executed by a processing arrangement, may cause at least one radiation generating arrangement to forward at least one first electromagnetic radiation to the sample via at least one optical fiber. The arrangement can include a second module, which when executed by a processing arrangement, may control at least one first characteristic of at least one portion of the optical fiber so as to modify at least one second characteristic of at least one second electromagnetic radiation generated within the optical fiber. The second electromagnetic radiation can be associated with the first electromagnetic radiation.

In yet another exemplary embodiment of the present invention, a method can be provided. In this exemplary method at least one electromagnetic radiation can be transmitted through at least one fiber arrangement and at least one filtering arrangement. The fiber arrangement may have optical transmitting characteristics and include therein the filtering arrangement. The electromagnetic radiation may be forwarded to at least one sample. The fiber arrangement may include at least one first fiber which can have characteristics that filter the electromagnetic radiation. The electromagnetic radiation can be received from the sample and filtered using at least one receiving arrangement. At least one portion of the fiber arrangement can be composed of and/or can include therein sapphire, diamond, clear graphite, Chalcogenide, borosilicate, zirconium fluoride, silver halide, a liquid core light guide, a gas core light guide, a hollow core waveguide, and/or a solid core photonic crystal fiber.

These and other objects, features and advantages of the present invention will become apparent upon reading the following detailed description of embodiments of the invention, when taken in conjunction with the appended claims.

### BRIEF DESCRIPTION OF THE DRAWINGS

Further objects, features and advantages of the invention will become apparent from the following detailed description taken in conjunction with the accompanying figures showing illustrative embodiments of the invention, in which:

FIG. 1A is an exemplary graph illustrating an idealized transmission profile for band-pass and notch filters for use in optical fiber probes for Raman spectroscopy;

FIG. 1B is an exemplary graph illustrating an idealized transmission profile for short-pass and long-pass filters for use in the optical fiber probes for the Raman spectroscopy;

FIG. 1C is an exemplary graph illustrating actual and idealized transmission profiles for collection and excitation filters for use in the optical fiber probes for the Raman spectroscopy;

FIG. 2 is a block and procedural diagram illustrating exemplary effects of certain filters which can be used to reduce or eliminate the luminescence generated in the optical fibers of Raman probes in accordance with an exemplary embodiment of the present invention;

FIG. 3A is a graph illustrating typical times for photo-molecular interactions of a fluorescence signal when using a picosecond pulsed laser for the excitation;

FIG. 3B is a graph illustrating typical times for photo-molecular interactions of a laser pulse, Raman signal and Rayleigh signal when using a picosecond pulsed laser for the excitation;

FIG. 4 is a graph of an exemplary time sequence for collected time-gated signals when using a pulsed laser to minimize collection of emitted fluorescence according to the an exemplary embodiment of the present invention;

FIG. 5 is a graph of an exemplary background generated in optical fibers scales as the square of the fiber's numerical aperture according to another exemplary embodiment of the present invention;

FIG. 6 is a block diagram of a system according to an exemplary embodiment of the present invention which uses a dual-clad fiber for Raman spectroscopy;

FIG. 7 is a block diagram of a system according to another exemplary embodiment of the present invention which uses fiber Bragg gratings as filters in exemplary Raman probes;

FIG. 8 is a side view of an exemplary embodiment of a Raman probe according to the present invention which uses a mirror or reflector to direct both the laser light and Raman scattered photons;

FIG. 9 is a side view of a further exemplary embodiment of a filter according to the present invention which can be helpful in removing the fiber background and laterally directing the light;

FIG. 10A is a side view of one exemplary embodiment of the filter which uses a grating to spatially filter the light and eliminate the fiber background;

FIG. 10B is a side view of another exemplary embodiment of the filter which uses the grating to spatially filter the light and eliminate the fiber background; and in which a dual-clad fiber can be used for delivery and collection;

FIG. 11 is a graph of an exemplary effect of a temperature on the ratio of emitted anti-Stokes and Stokes Raman photons;

FIG. 12 is a general block diagram of a procedure for implementing time-gated techniques in the Raman spectroscopy to eliminate collection of sample fluorescence according to an exemplary embodiment of the present invention;

FIG. 13A is an illustration of a cross-section of a first exemplary embodiment of a fiber arrangement according to the present invention which includes an integral insulation;

FIG. 13B is an illustration of a cross-section of a second exemplary embodiment of the fiber arrangement according to the present invention which includes the integral insulation;

FIG. 14 is a diagram of n exemplary embodiment of a cooling method according to the present invention using an exemplary cooling mechanism housed within the apparatus which may include one or more optical fibers; and

FIG. 15 is an illustration of a cross-section of a third exemplary embodiment of the fiber arrangement according to the present invention which includes the integral insulation.

Throughout the figures, the same reference numerals and characters, unless otherwise stated, are used to denote like features, elements, components or portions of the illustrated embodiments. Moreover, while the subject invention will now be described in detail with reference to the figures, it is done so in connection with the illustrative embodiments. It is intended that changes and modifications can be made to the described embodiments without departing from the true scope and spirit of the subject invention as defined by the appended claims.

### DETAILED DESCRIPTION OF EMBODIMENTS OF THE INVENTION

### Summary of Exemplary Optical Fiber Probe Design

Exemplary Fiber Selection

Catheters and endoscopes capable of delivering light to and from a sample are important for a practical application of Raman spectroscopy, e.g., in the field of medicine. In general, this can be accomplished using optical fibers. For example, low-OH fused silica core/fused silica clad fibers can be implemented for this purpose, as described in M. Shim et al., “Development of an In Vivo Raman Spectroscopic System for Diagnostic Applications,” J Raman Spectrosc, Vol. 28, p. 131 (1997). However, the use of such fibers may also be problematic. The material of the fiber is Raman active. As the excitation light travels down the core, a large fiber background signal (which can overlap the spectral fingerprint region of most materials) can be generated which propagates along this fiber. This background can be elastically scattered by the sample, and may reach the detector in the same or substantially similar manner as the signal of interest. Further, a portion of the excitation light can also be reflected from the sample, and may cause the same or similar effect in the fibers used for collection, as described in R. L. McCreery, “Raman Spectroscopy for Chemical Analysis, Chemical Analysis: A Series of Monographs on Analytical Chemistry and Its Applications,” John Wiley & Sons, Inc., Vol. 157, p. 420 (2000).

With respect to the detection of the electromagnetic radiation, a signal of a given intensity is likely associated with a certain level of noise. Such noise can be referred to as “shot noise,” and its amplitude may be equal to or approximately the square root of the detected signal. Therefore, the background that is generated in the fibers and gathered by the detection system also contributes noise to the final signal of interest. It is possible that this noise may be greater in amplitude than the Raman signal from the sample, thus resulting in mostly useless data with SNR<1.

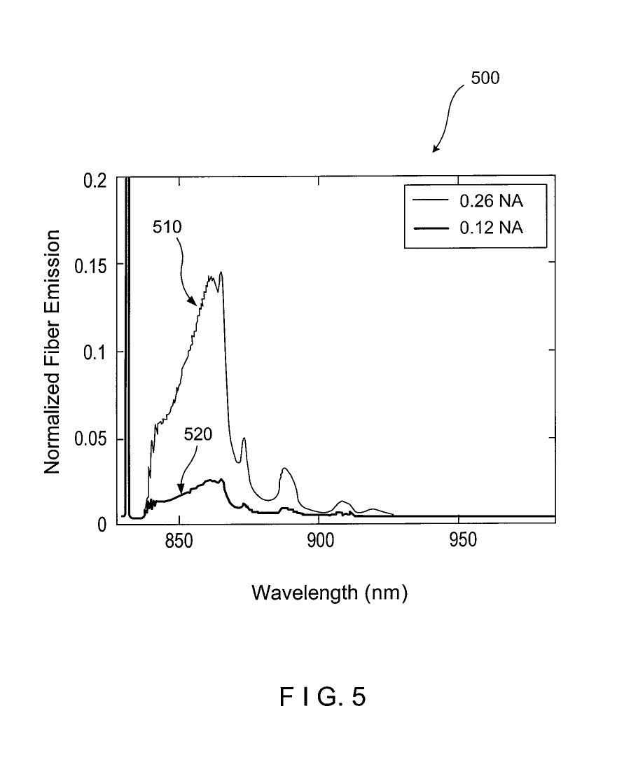

It is possible to control the amplitude of this fiber background by selecting the appropriate numerical aperture (NA) fibers. For example, as shown in the graph of FIG. 5, the intensity of the background can be scaled as NA2, as described in J. Ma et al., “Fiber Raman Background Study and its Application in Setting Up Optical Fiber Raman Probes,” Applied Optics, Vol. 35(15), p. 2527 (1996). Thus, a selection of a lower NA can reduce the background signal. However using such procedure, it may generally not be sufficient to reduce the shot noise to a manageable level. Furthermore, lower NA fibers can result in a lower collection efficiency, thereby likely reducing the signal of interest.

According to an exemplary embodiment of the present invention, further materials and designs not previously available may provide superior optical fibers that can produce minimal background, thereby increasing SNR. These may include, but are not limited to, e.g.:
Alternate materials: sapphire, diamond or clear graphite, Chalcogenide, zirconium fluoride, and silver halide
Liquid core light guides (e.g. DuPont's Teflon AF tubing) filled with water, deuterium, or other liquids with low Raman activity
Gas core light guides
Hollow core waveguides: metallic, dielectric (c.f. OmniGuide, http://www.omni-guide.com/), photonic crystal (“holey”) fiber (c.f. Crystal Fibre, http://www.blazephotonics.com/), or light guiding capillary tubing (c.f.www.polymicro.com/products/capillarytubing/products capillaryt ubing_ltsp.htm)
Solid core photonic crystal fiber (c.f. Crystal Fibre, http://www.blazephotonics.com/)

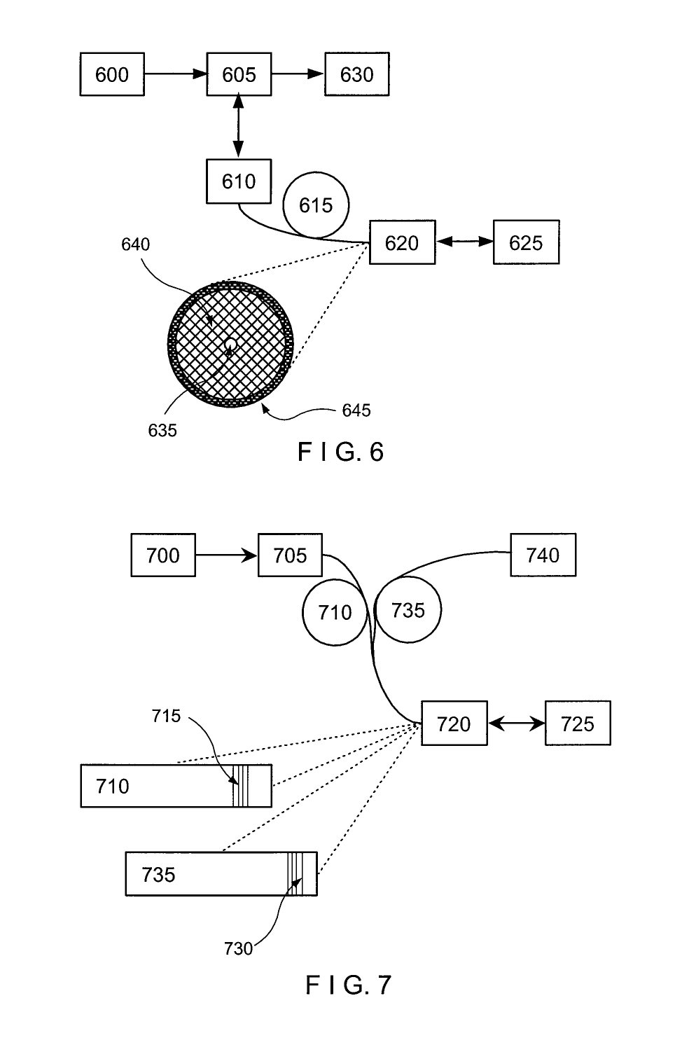

In addition, dual (or double) clad fibers, e.g., the solid core and cladding type or the photonic crystal type, can provide a particular geometry for a remote Raman spectroscopy. Instead of implementing the conventional n-around-1 geometry with a central excitation fiber and n surrounding collection fibers, the central core of a dual clad fiber can be used for an excitation, while the inner cladding can be for collecting the Raman scattered light. Particular filters can be registered with or written onto the core and inner clad of such fibers as shown in the exemplary embodiment of the system illustrated in FIG. 6, and as further discussed herein below.

In addition, dual (or double) clad fibers, e.g., the solid core and cladding type or the photonic crystal type, can provide a particular geometry for a remote Raman spectroscopy. Instead of implementing the conventional n-around-1 geometry with a central excitation fiber and n surrounding collection fibers, the central core of a dual clad fiber can be used for an excitation, while the inner cladding can be for collecting the Raman scattered light. Particular filters can be registered with or written onto the core and inner clad of such fibers as shown in the exemplary embodiment of the system illustrated in FIGS. 6 and 9, and as further discussed herein below.

### Filtering Techniques

Even with the proper selection of fiber material/design, significant background signal may still compromise SNR, and detract from an accurate analysis of the sample's Raman spectrum. In such cases, it may be preferable to provide one or more filters at the distal ends of the excitation and collection fiber(s). Thus, fiber Bragg gratings can be provided into the core at the end of the optical fibers, as shown in a block diagram of FIG. 7. The fibers can be single-mode or multi-mode fibers, and may include step-index or graded-index cores. These gratings can be specifically tuned to reject or block various wavelength regions, and thus can be used in stead of or in addition to the traditional holographic or dielectric filters. A short-wavelength pass or band-pass filter can be provided into the delivery fiber to reject luminescence generated in the fiber and pass the laser light to the sample. The collection fiber(s) can include a notch-type or long-wavelength pass filter to at least partially block the elastically scattered light from the sample, and pass the Raman scattered light from the sample.

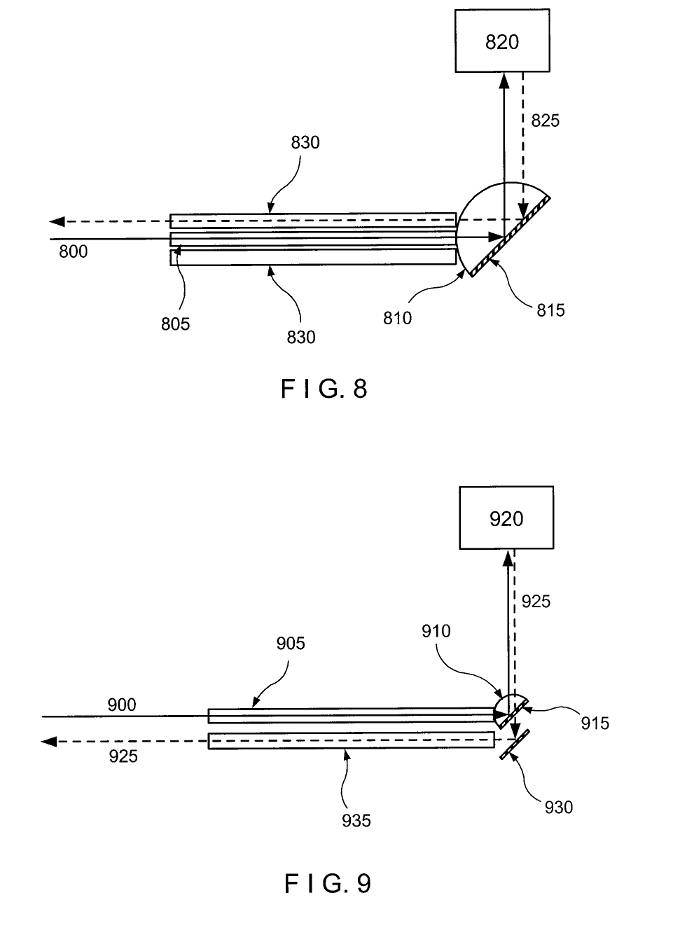

Various types of reflectors (e.g. dielectric stack filters) can be used to simultaneously filter the optical signals and direct this light to the appropriate location (e.g. side/lateral/circumferential-viewing geometries). For example, a fiber registered with, or monolithically terminated with a ball (or other type) lens can be provided, an example of which is shown in FIG. 8, the details of which shall be discussed herein below. Such exemplary lens can be is polished to an angle can have a mirror on the polished surface to deflect the beam at an angle. The mirror can be replaced or modified by a filter may be deposited on or placed behind (and parallel to) the polished surface to deflect the appropriate wavelengths, the example of which is shown in FIG. 9, and described in further detail below.

Various types of reflectors (e.g. dielectric stack filters) can be used to simultaneously filter the optical signals and direct this light to the appropriate location (e.g. side/lateral/circumferential-viewing geometries). For example, a fiber registered with, or monolithically terminated with a ball (or other type) lens can be provided, an example of which is shown in FIG. 5, the details of which shall be discussed herein below. Such exemplary lens can be is polished to an angle and can have a mirror on the polished surface to deflect the beam at an angle. The mirror can be replaced or modified by a filter which may be deposited on or placed behind (and parallel to) the polished surface to deflect the appropriate wavelengths, the example of which is shown in FIG. 8, and described in further detail below.

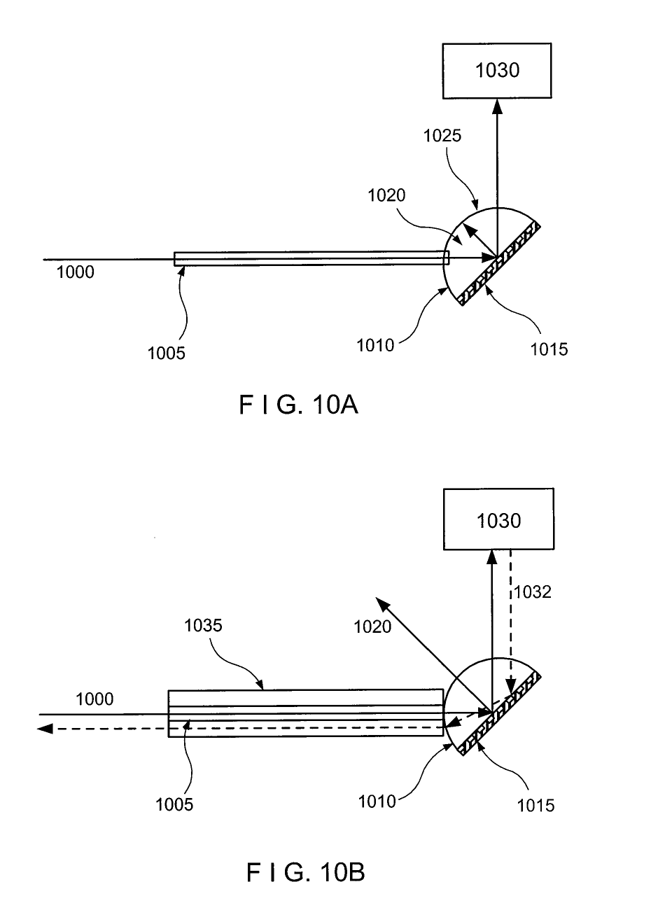

Filtering of the signals can also be accomplished by spectral separation. Gratings at the distal end of the fibers can be used to selectively deflect appropriate wavelengths. For example, the polished surface of the above mentioned lens can be imprinted with a grating, thereby deflecting the desired wavelengths with an angular spread that is spectrally centered orthogonal to the long axis of the optical fiber, as shown in the arrangements of FIGS. 10A and 10B, and described in more detail below. The undesired wavelengths can be blocked by absorptive (or reflective) elements deposited on the exit surface of the lens lateral to the transmission window. This exemplary configuration can be suited for the excitation path.

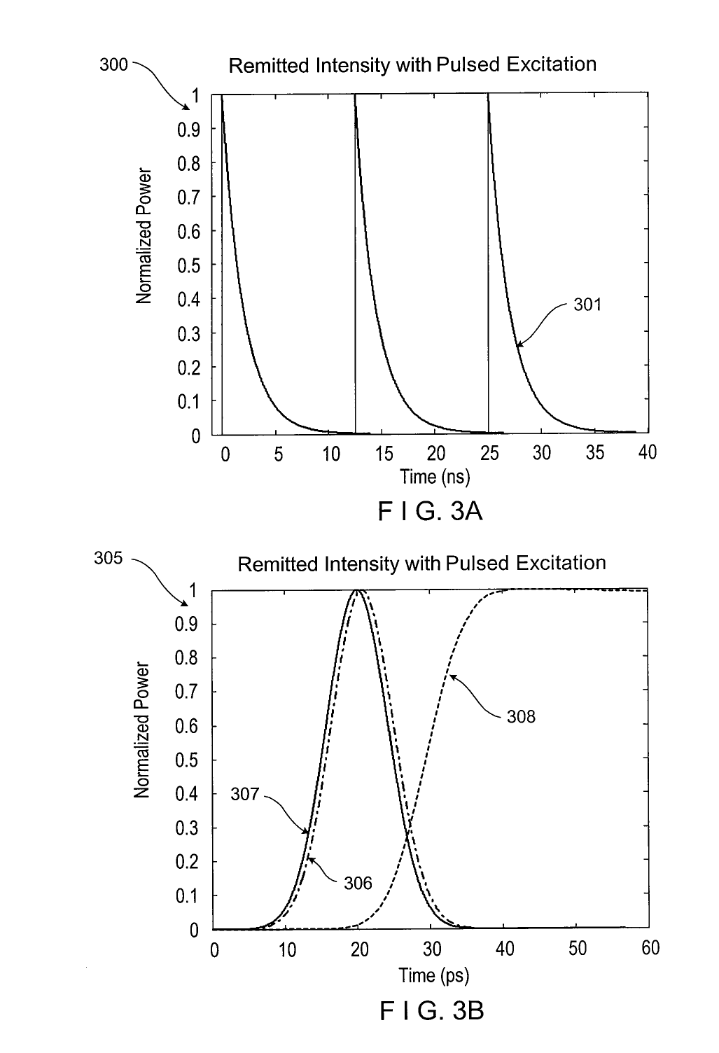

A temperature modulation of the optical fibers can assist in spectral filtering. The ratio of Raman scattered photons that are anti-Stokes shifted (e.g., to shorter wavelengths) relative to those which are Stokes shifted (e.g., to longer wavelengths) from the excitation wavelength can be increased with temperature, as shown in the graph of FIG. 3, e.g., associated with number of molecules in excited vibrational states according to the Boltzmann distribution

$$\frac{{I}_{AS}}{{I}_{S}} = {( \frac{{v}_{i} + {v}_{vib}}{{v}_{i} - {v}_{vib}} )}^{4} {e}^{- {hv}_{vib} / kT} \qquad ( 1 )$$

where I_{AS} and I_{S} are the intensities of the anti-Stokes and Stokes emitted light, respectively, vᵢ and v_{vib} are the frequency of the excitation and emitted photons, respectively, h is Planck's constant, k is the Boltzmann constant, and T is temperature. Temperature modulation (optically or electrically) of the excitation fiber will create a shift in the anti-Stokes/Stokes ratio of Raman scattered photons from the fiber, allowing a temporal frequency filter to separate the fiber background photons from sample Raman photons which are not thermally modulated.

### Exemplary Minimization of Non-Raman Sample Luminescence

Certain applications of Raman spectroscopy can be inhibited by an intense fluorescence from the sample and its associated shot noise which can overwhelm the observation of the Raman emission of interest, often even in the presence of resonance enhancement of the Raman signal. This is particularly the case for a biological Raman spectroscopy where the Raman scattering may not typically be detected with a visible excitation. Ultraviolet excitation allows for the observation of the Raman emission because it is sufficiently spectrally separated from the fluorescence. However, these exemplary wavelengths are mutagenic and have very limited penetration in tissue. And even with UV excitation, the problems of fiber background persist. Excitation by pulsed lasers has at least two potential mechanisms to reduce collection of fluorescent signals: photo-bleaching and time resolution.

Photo-Bleaching

The increased temporal energy density of pulsed lasers causes photo-bleaching of the tissue autofluorescence due to depopulation of the ground state, thereby reducing the confounding emission. The duration between fs or picosecond (ps=10⁻¹² s) pulses can allow a sufficient diffusion of heat induced by absorption to prevent thermal damage, especially in regions with natural cooling mechanisms, such as blood flow in the vascular system. Studies have shown that significant photo-bleaching can occur below the energy densities that result in a histological evidence of arterial tissue damage, even in the absence of blood flow, as described in J. T. Motz, “Development of In Vivo Raman Spectroscopy of Atherosclerosis,” Ph.D. Thesis, Massachusetts Institute of Technology, Cambridge, 2003.

Time Gating

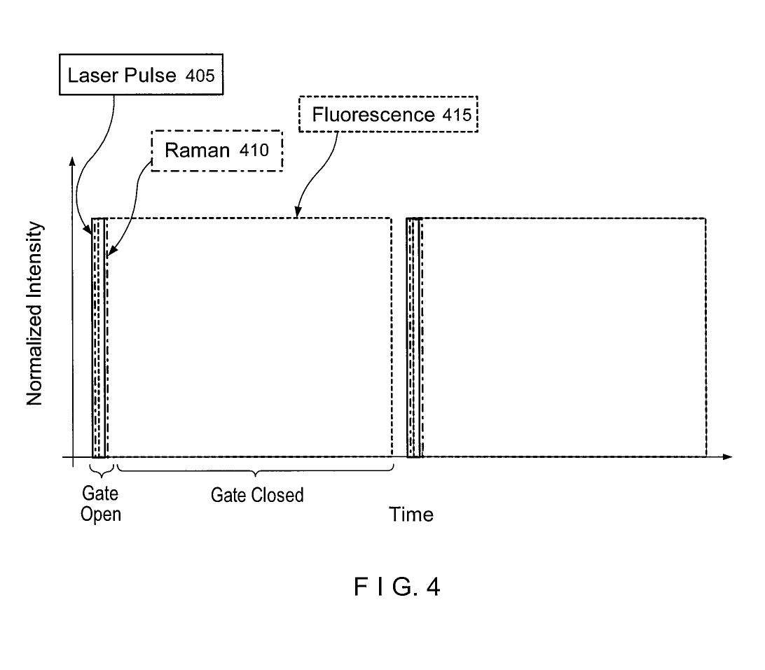

Pulsed lasers generally allow gating of collection using certain techniques due to the temporal difference in various photo-molecular interactions. Resonance Raman scattering, which uses the absorption and interaction with the excited electronic states may have emission lifetimes on the order of 10⁻¹⁴ s (10 fs); non-resonant Raman scattering occurs at even faster rates. In contrast, the majority of fluorescence emission occurs with lifetimes on the order of nanoseconds. By using picosecond pulsed lasers, these signals can be temporally separated to eliminate collection of interfering fluorescence emission, as shown in the graphs of FIGS. 3A, 3B and 4. Preferably, pulse durations of ˜10 ps can be employed to provide sufficiently narrow excitation line widths which can maintain a Raman spectral resolution. The detection system can then be configured to collect light from the arrival of the excitation pulse for a duration that ends prior to some or all of the fluorescence emission. This provides for a collection of substantially all of the Raman light with possibly a small contamination of the background signal. This exemplary embodiment of a procedure according to the present invention can provide sufficient fluorescence elimination to enable the visible excitation, thereby taking advantage of the v⁴ dependence of the Raman scattering intensity (see Eq. 1 above).

### Exemplary Minimization of Fiber Generated Background

In addition, possibly due to the finite time of the photon propagation (˜1 foot/ns), it is also possible to eliminate at least a majority of the fiber background generated in the excitation fiber via time gating using an optical fiber Raman probe, e.g., several meters in length. The fiber background generated in the excitation fiber should be reflected from the sample, and gathered by the collection fibers for delivery to the detector. If the detector is not gated on, e.g., until slightly after the excitation pulse reaches the tissue, a large fraction of the fiber background may not be detected because the specular reflection of this signal may occur before the Raman emission. This greatly simplifies the filtering requirements in the optical fiber probe itself.

Exemplary gating procedures can include optical or electronic-related procedures as shown an exemplary functional block diagram of FIG. 5. Exemplary optical procedures can include the use of Kerr cells and Pockel cells. Exemplary electronic gating can include the use of streak cameras, rapid (ns) response photodiode arrays, micro-channel plate detectors, or homodyne detection. The inclusion of optical fibers may possibly utilize a dispersion compensation or the use of dispersion-free fibers.

### Exemplary Optical Fiber Probe Arrangement and Process

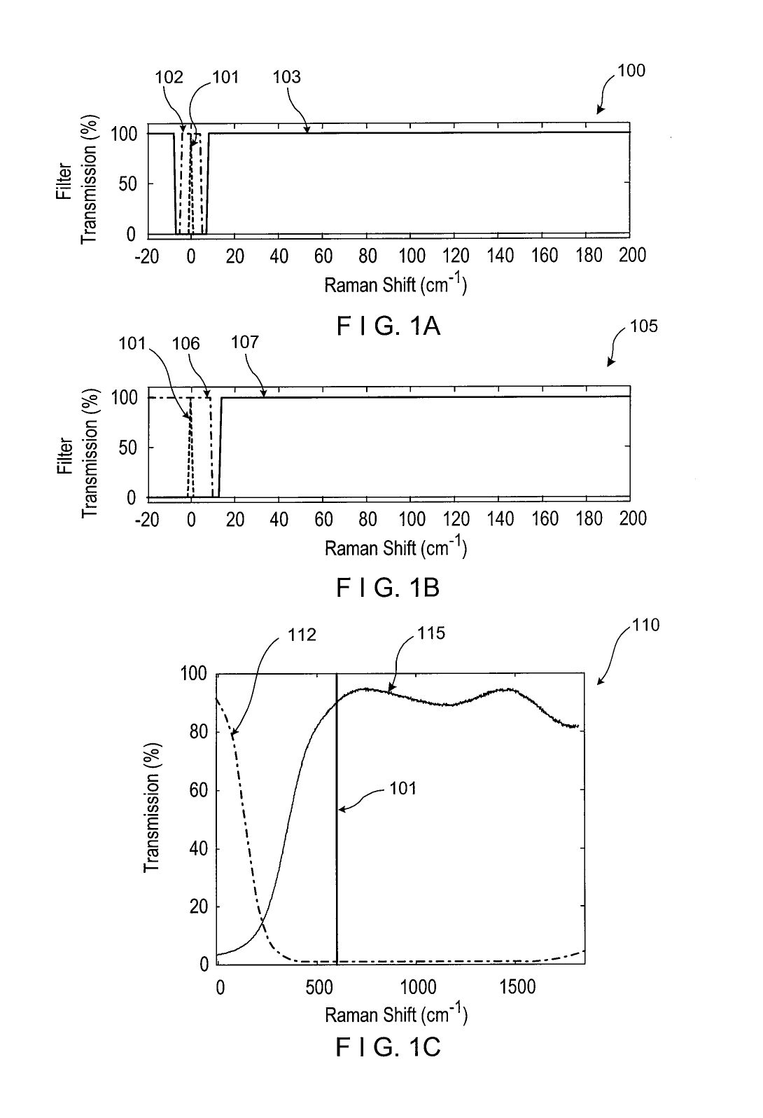

A graph 100 of FIG. 1A shows an exemplary graph of an idealized filter transmission profile for use in an optical fiber Raman probe. For example, the laser profile 101 is shown at 0 cm⁻¹. The band-pass filter which passes the laser light but blocks all other wavelengths, including spontaneous emission from the laser and background luminescence generated in optical fibers, can be placed at the distal end of the excitation fiber and/or provided into the fiber as a Bragg grating. This exemplary filter enables an excitation of the sample but likely prevents the fiber background from reflecting from the sample and entering the collection path. The exemplary profile 102 of the signal passed through the band-pass filter is also shown in FIG. 1A. The notch filter, which can transmit wavelengths that may be longer and/or shorter than that of the laser, may be placed at the distal end of the collection fibers or provided therein as Bragg gratings. This notch filter can prevent the elastically scattered laser light from entering the collection, thereby preventing the generation of additional fiber background. The use of the notch-type filter can also allow the Raman probe to be used for the observation of anti-stokes Raman scattering. An exemplary profile 103 of the signal passing through the notch filer is shown in FIG. 1A.

A graph 105 of FIG. 1B shows the transmission profiles of two further types of filters which can be utilized instead of or in conjunction with the filters described above with reference to FIG. 1A. A short-pass filter that can transmit the laser and may reflect longer wavelengths can take the place of the band-pass filter described above at the distal end of the excitation fiber. The exemplary profile 106 of the signal passing through the short-pass filter is shown in FIG. 1B. A long-pass filter which can reflect the laser wavelength and may transmit the longer wavelengths can be uses as an alternative to the notch filter at the distal end of the collection fiber(s). The exemplary profile 107 of the signal passing through the long-pass filter is shown in FIG. 1B.

A graph 110 of FIG. 1C shows examples of the transmission curves for the short-pass filter and the long-pass filter that can be realized with dielectric filters. The exemplary profile 112 of the signal passing through an excitation filter, and the exemplary profile 115 of the signal passing through a collection filter are shown in FIG. 1C.

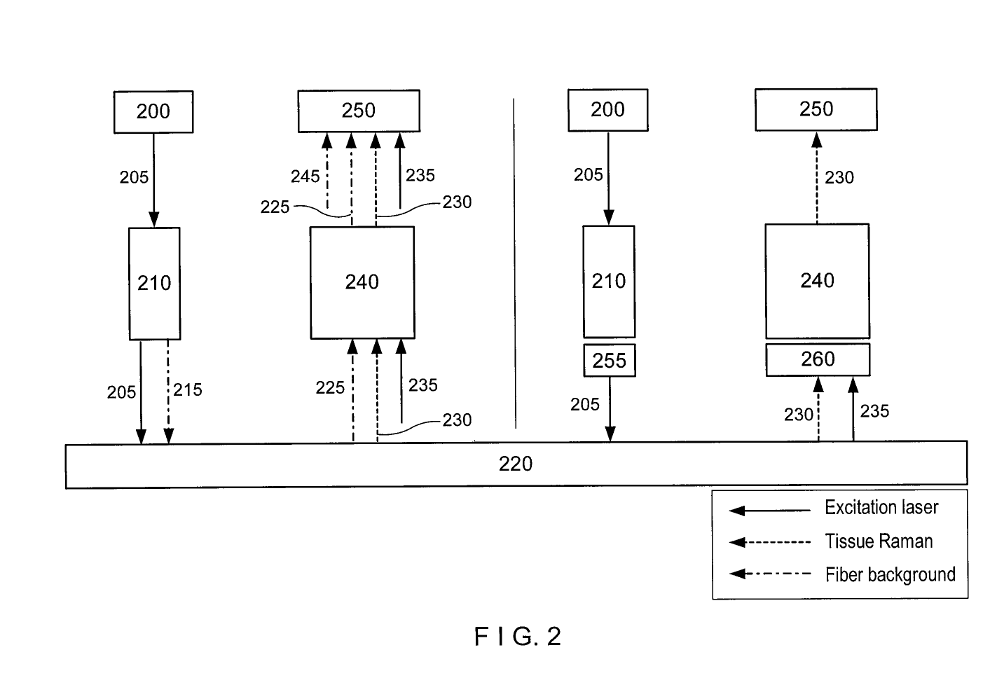

FIG. 2 depicts a functional block diagram of an exemplary embodiment of a procedure according to the present invention in which the signals interact with the filters that can be used at the distal end of a Raman probe. For example, on the left-hand side of FIG. 2, an interaction which uses unfiltered fibers is shown. For example, an excitation light 205 from a laser source or a filtered broadband source can be coupled into unfiltered excitation fiber 210. As this light 205 travels down a fiber 210, a background luminescence 215 can be generated, which then also travels down the fiber 210, subsequently exiting from the fiber 210, and impacting the sample 220. The fiber background 215 can be diffusely scattered and/or specularly reflected from the sample 220. This reflected light 225 can enter an unfiltered collection fiber 240, and possibly be transmitted to a detector 250. A portion of the laser light 205 can also be diffusely scattered and/or specularly reflected from the sample 220, and enter the collection fiber 240. Such reflected laser light 235 can generate a further fiber luminescence 245 in the collection fiber(s) 240 which may be transmitted to the detector 250. The Raman signal 230 generated in the sample can also be transmitted to the detector 250 through the collection fiber 240.

The right-hand side of FIG. 2 shows the exemplary functionality of the filters which can be used in a Raman probe. The light 205 from source 200 can enter the excitation fiber 210, and may be transmitted through filter 255 to the sample 220. The fiber background 215 of the left-hand side of FIG. 2 can be blocked by the filter 255, which can be a short-pass filter and/or band-pass filter. The background 215 does not, therefore, have to reach the sample 220 or the detector 250. The reflected laser light 235 can be blocked from entering the collection fiber 240 by the filter 260, which can be a notch filter or a long-pass filter, thereby preventing generation of fiber luminescence in the collection fiber 240. The generated sample Raman can be passed by the filter 260 for a transmission to the detector 250 by the collection fiber 240.

FIG. 5 shows an exemplary graph 500 of a Raman spectra of two different fused silica optical fibers with different NAs. The more intense spectrum 510 can be generated by a fiber with NA=0.26, while the weaker spectrum 520 may be generated from a fiber with NA=0.12. In this manner, the NA² dependence of background intensity can be demonstrated.

FIG. 6 shows a block diagram of an exemplary embodiment of a system according to the present invention which uses a double fiber or a dual-clad fiber for the Raman spectroscopy. For example, the light from a laser 600 can be split by a beam splitter or deflected by a dichroic mirror or a filter such that the laser light is directed to optics 610 for coupling into a central core 635 of a dual-clad fiber 615. Illumination and collection optics 620 can forward the laser to a sample 625, and collect the Raman scattered light returning from the sample 625. The Raman scattered light can be provided to an inner cladding 640 of the dual-clad fiber 615. The light emerging from the fiber 615 can be deflected by a beam splitter or dichroic filter 605 and directed to detector 630. The dichroic filter can be a notch filter, a band-pass filter, a long-pass filter, or a short-pass filter possibly oriented in an appropriate manner. The filter can be of the holographic, dielectric or other type. The appropriate transmission filters can be placed on the distal end of the fiber sections or placed in registration with them. Alternately, fiber Bragg gratings can be provided into the fiber 615 to provide certain filtering capabilities.

FIG. 7 a block diagram of another exemplary embodiment of a system according to the present invention which uses fiber Bragg gratings as the filters in the optical fiber probes for Raman spectroscopy. For example, the light from a laser 700 can be provided to an excitation fiber 710 by coupling optics 705. The background luminescence generated in the fiber 710 can be reflected by the fiber Bragg grating 715 to prevent it from reaching a sample 725. The fiber Bragg grating 715 can be a band-pass grating or a short-pass grating. The laser light may be transmitted to the sample 725 via illumination and collection optics 720. The Raman scattered light can be provided to a fiber 735 by illumination and collection optics 720. Rayleigh or diffusely scattered laser light is prevented from entering fiber 735 by fiber Bragg grating 730 which can be of the notch- or long-pass type. The transmitted signal may then be provided to a detector 740.

FIG. 8 shows a side view of a Raman probe according to an exemplary embodiment of the present invention. For example, the probe can be modular, e.g., distal optics 810 may be separate units from the optical fibers 805 and 830, and/or monolithic where the optics 810 may be created by fusing and shaping the distal end of the fibers. A laser light 800 may travel down an excitation fiber 805 with the appropriate filtering, and enter the distal optics 810 which could be a hemi-spherical lens or another type of a lens. The optics 810 are supported by a reflector which can redirect the laser light 800 to a side for the illumination of the sample 820. The generated Raman scattered light may be gathered by the optics 810, and directed by a reflector 815 to an appropriately filtered collection fiber(s) 830.

FIG. 9 shows a side view of another exemplary embodiment of the Raman probe of the present invention, in which a filter may be used to redirect the laser light from a modular or monolithic excitation fiber. A laser light 900 can be transmitted through a fiber 905 to distal optics 910 which may be supported by a dichroic filter that passes the fiber background through the front of the probe, and can deflect the laser to a sample 920 on the side. Raman scattered light 925 is gathered by optics 910, passed through dichroic filter 915 and reflected by a mirror 930 to be directed into a collection fiber 935. The filter 915 can also reflect the Rayleigh scattered laser light, thereby likely preventing the generation of a fiber background in the collection fiber 935. Alternately, collection fiber 935 could be angle cleaved such that the Raman scattered light is directed into the fiber through total internal reflection, without the use of the mirror 930.

FIGS. 10A and 10B show block diagrams of two versions of still another exemplary embodiment of a Raman probe. For example, in one exemplary version shown in FIG. 10A, a grating is used only for the excitation fiber. The distal optics can be supported by a grating which can, in one exemplary approach, be stamped onto the optics. A laser light 1000 traveling along a fiber 1005 can enters distal optics 1010, and may be deflected by a grating 1015 to a sample 1030. A fiber background 1020 can be deflected at a different angle, and prevented from reaching the sample by a reflector or an absorbing layer 1025 placed on a lateral face of the optics 1010. A separate path may be used for the collection. In another exemplary version shown in FIG. 10B, a dual clad fiber (as shown in FIG. 6) can be used. In this exemplary version, an absorber or reflector is not placed on or in the optics 1010. Similarly to the previously-described version, the laser can travel along the core of the dual-clad fiber 1005, and may be deflected by the grating 1015 to the sample 1030. The fiber background 1020 can be deflected to a more lateral position away from the illuminated area. A Raman scattered light 1032 can be gathered by the collection optics 1010, and deflected to the inner cladding 1035 of the dual-clad fiber by grating 1015.

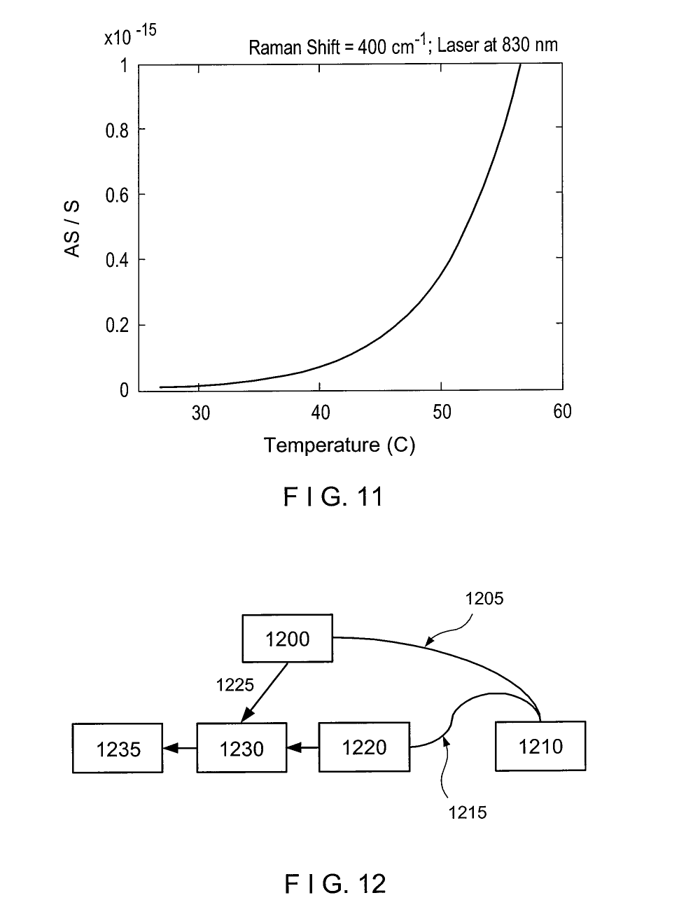

FIG. 11 shows a graph providing an exemplary ratio of anti-Stokes to Stokes shifted Raman as described above in Equation 1. The modulation of the temperature, optically and/or electrically, can shift the amount of Raman emitted photons back and forth from anti-Stokes to Stokes shifted emission, thereby likely producing an amplitude modulation of the fiber background. The signal from the tissue would not be modulated, and therefore such signal can be differentiated from the fiber background.

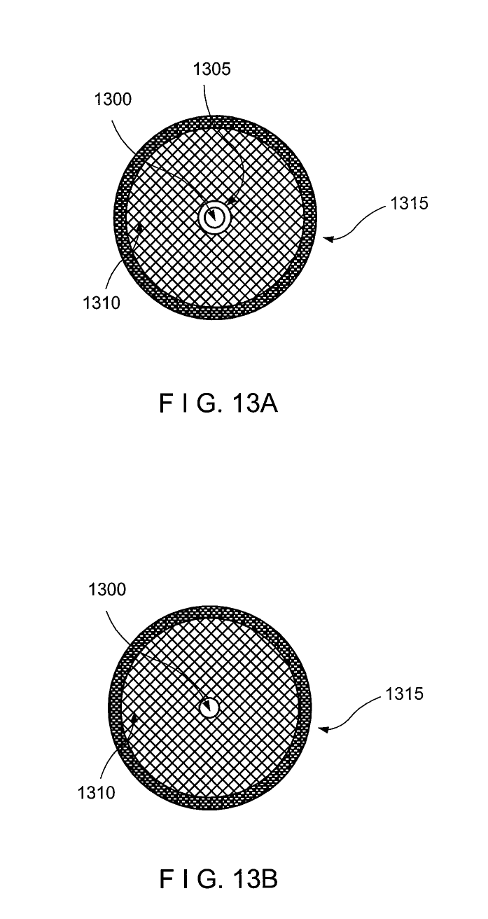

In certain cases where the environment surrounding the optical fiber are sensitive to temperature changes, the protection of the environment may be at issue. This can be addressed, e.g., by insulating the heating element and fiber from the surrounding environment, and/or providing a cooling mechanism. Such cooling mechanisms could be integral to the fiber system or provided externally thereto. According to one exemplary embodiment of the present invention, such fiber should have a sufficient conductivity to provide sufficient modulation frequencies. However, the conductivity of the cooling medium can be such that it does not transfer heat to the surrounding environment. According to one exemplary embodiment of an external cooling mechanism of the present invention, it is possible to provide a saline flush around the fiber to dissipate heat in the environment. Exemplary embodiments of fiber arrangements which include integral insulation are shown in FIGS. 13A, 13B and 15, and exemplary embodiments of a cooling method according to further exemplary embodiments of the present invention is shown in FIG. 5.

For example, FIG. 13A shows a cross-section of a first exemplary embodiment of the fiber arrangement according to the present invention which includes an integral insulation. For example, the optical fiber 1300 can be heated electrically using a heating element 1305, and the generated heat may be confined to the fiber 1300 through an insulating material 1310. A similar insulating arrangement, e.g., a second exemplary embodiment of the fiber arrangement according to the present invention as shown in FIG. 13B, can be employed by optically heating the fiber 1300, where the heating element 1305 is not shown.

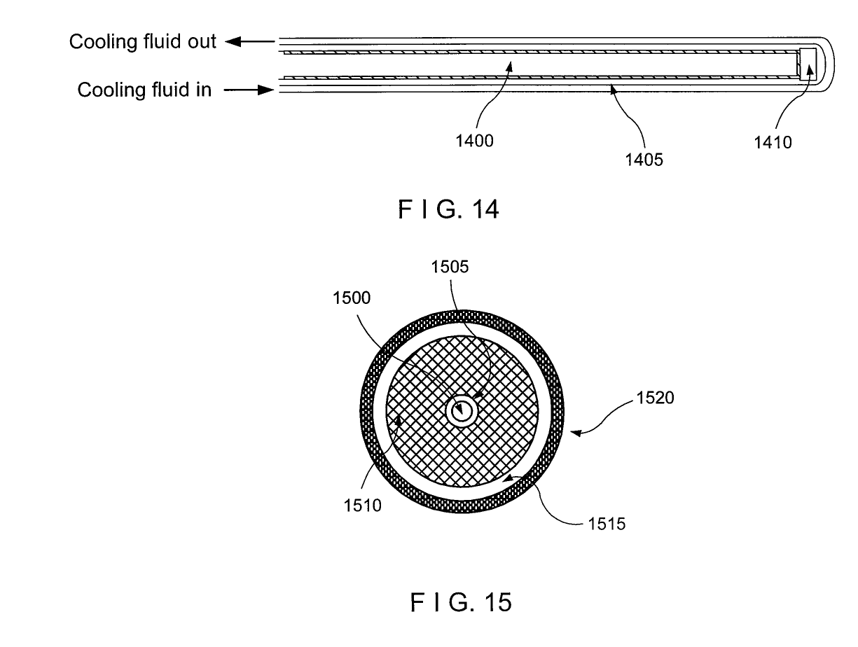

FIG. 14 shows an exemplary embodiment of a cooling method according to the present invention which can utilize an exemplary cooling mechanism housed within the exemplary apparatus that may include one or more optical fibers 1400. For example, a liquid transfer system can be included within the apparatus to shield the environment from the heating of the optical fiber(s) 1400, and be transmitted via a circulation element 1405 and around distal optics 1410. Liquids such as water or those with low conductivity and low viscosity can be used for such cooling so that rapid flow and minimal heat transfer can be maintained.

FIG. 15 shows a cross-section of a third exemplary embodiment of the fiber arrangement 1520 according to the present invention which includes the integral insulation. This exemplary fiber arrangement 1520 includes a separate cooling element 1515 which is provided in the fiber arrangement 1520 to maintain an appropriately low temperature at the boundary between the arrangement and the environment. For example, the cooling element 1515 can encompass the fiber 1500, the heating element 1505 and the insulating material 1510.

### Exemplary Minimization of Non-Raman Sample Luminescence

FIGS. 3A and 3B show graphs 300, 305 of exemplary time sequences for several photo-molecular interactions in a biological tissue, e.g., modeling the remitted light along with an incident laser pulse. The simulation assumed a picosecond (10⁻¹² s FWHM) pulsed laser 307 with an 80 MHz repetition rate and a fluorescence emission 301 with a lifetime which decays as e^{-t/τ}, where τ is the fluorescence lifetime, and may be assumed to be 2 ns. For example, the remitted Rayleigh scattered light 309 was assumed to follow a t^{-3/2} profile, while remitted Raman photons 306 were modeled with a t^{-1/2} profile, as described in N. Everall et al., “Picosecond time-resolved Raman spectroscopy of solids: Capabilities and limitations for fluorescence rejection and the influence of diffuse reflectance,” Applied Spectroscopy, Vol. 55(12), p. 1701 (2001). The graph 300 of FIG. 3A shows 3 successive exemplary laser pulses and the Raman and Rayleigh scattered light, along with the fluorescence, all of which were normalized to their maximum signal. On the scale shown in FIG. 3A, the fluorescence decay can be visualized; however, the laser pulse 307 may be indistinguishable from the Rayleigh re-emission 309 and the Raman re-emission 306. The graph 305 of FIG. 3A shows a magnification of one pulse of the graph 300. In FIG. 3B, the remitted Rayleigh scattered light 309 can be seen as closely following the laser pulse 307, while the Raman scattering 306 emerges from the tissue with a slight delay, and before the peak of the fluorescence emission 301.

FIG. 4 shows a graph of an exemplary potential time sequence according to an exemplary embodiment of the present invention for avoiding a collection of fluorescence from samples. For example, the laser pulse (solid line) 405 is followed by the Raman scattering (dashed line) 410 as described above with reference to FIGS. 3A and 3B. The fluorescence signal 415 can be slightly delayed, and may continue for a particular period of time which may be shorter than the duration between the laser pulses. A gating mechanism, which can be, but is not limited to, e.g., a Kerr or Pockel cell or a gated optical imager, may be opened for the duration of the laser pulse or slightly longer to allow for a collection of the Raman scattered light. The gate can then be closed before the fluorescence emission peaks, thereby likely preventing a detection of such unwanted signal. The gate can be reopened at the next pulse.

FIG. 12 shows a block diagram of a system according to an exemplary embodiment of the present invention for obtaining time gated measurements which can be used to minimize collection of the fluorescence emitted from a sample being examined for the Raman spectroscopy. For example, a laser 1200 can provide a laser light to a fiber 1205, and directed to a sample 1210. The emitted luminescence may be transmitted by appropriate collection optics and collection fiber(s) 1215 to collimating optics 1220. The collimated light may then be passed through a triggered gating mechanism 1230 which mat be triggered by an optical or electrical pulse 1225 from the laser 1200 that can open the gate for the duration of the laser pulse and potentially for a certain period of time thereafter. The transmitted light can then be transmitted to a spectrometer/detector for evaluation.

The foregoing merely illustrates the principles of the invention. Various modifications and alterations to the described embodiments will be apparent to those skilled in the art in view of the teachings herein. Indeed, the arrangements, systems and methods according to the exemplary embodiments of the present invention can be used with imaging systems, methods and procedures, and for example with those described in International Patent Application PCT/US2004/029148, filed Sep. 8, 2004, U.S. patent application Ser. No. 11/266,779, filed Nov. 2, 2005, and U.S. patent application Ser. No. 10/501,276, filed Jul. 9, 2004, the disclosures of which are incorporated by reference herein in their entireties. It will thus be appreciated that those skilled in the art will be able to devise numerous systems, arrangements and methods which, although not explicitly shown or described herein, embody the principles of the invention and are thus within the spirit and scope of the present invention. In addition, to the extent that the prior art knowledge has not been explicitly incorporated by reference herein above, it is explicitly being incorporated herein in its entirety. All publications referenced herein above are incorporated herein by reference in their entireties.

1. A system, comprising:
at least one fiber arrangement including optical transmitting characteristics, configured to transmit there through at least one electromagnetic radiation and forward the at least one electromagnetic radiation to at least one sample, wherein at least one portion of the at least one fiber arrangement is composed of or includes therein at least one of sapphire, diamond, clear graphite, Chalcogenide, borosilicate, zirconium fluoride, silver halide, a liquid core light guide, a gas core light guide, a hollow core waveguide, or a solid core photonic crystal fiber; and
at least one receiving arrangement configured to receive the electromagnetic radiation that is filtered and received from the at least one sample.

2. The system according to claim 1, the at least one fiber arrangement including therein at least one filtering arrangement, and wherein the at least one fiber arrangement and the filtering arrangement are configured to transmit there through the at least one electromagnetic radiation and forward the at least one electromagnetic radiation to the at least one sample.

3. The system according to claim 1, wherein the at least one receiving arrangement includes therein at least one further filtering arrangement which is adapted to filtered the received at least one electromagnetic radiation.

4. The system according to claim 3, wherein the at least one receiving arrangement is at least one further fiber arrangement which has optical transmitting characteristics.

5. The system according to claim 1, wherein the received at least one electromagnetic radiation is a Raman radiation associated with the at least one sample.

6. The system according to claim 1, further comprising a further arrangement configured to house therein at least one portion of the at least one fiber arrangement.

7. The system according to claim 1, wherein the at least one sample is provided at least partially within an anatomical structure.

8. The system according to claim 1, wherein the at least one receiving arrangement includes a fiber arrangement which is composed of or includes therein at least one of sapphire, diamond, clear graphite, Chalcogenide, borosilicate, zirconium fluoride, silver halide, a liquid core light guide, a gas core light guide, a hollow core waveguide, or a solid core photonic crystal fiber.

9. The system according to claim 1, wherein the at least one fiber arrangement includes at least one first fiber which has at least one first filtering characteristic that filter the electromagnetic radiation, and wherein the at least one receiving arrangement is configured to receive the electromagnetic radiation that is filtered by at least one of the at least one first fiber or at least one second fiber which has the at least one second filtering characteristic that filter the at least one electromagnetic radiation.

10. The system according to claim 1, wherein the at least one fiber arrangement and the at least one receiving arrangement are the same.

11-12. (canceled)

13. A system, comprising:
at least one fiber arrangement which has optical transmitting characteristics, the at least one fiber arrangement including therein at least one filtering arrangement, wherein the at least one fiber arrangement and the at least one filtering arrangement are configured to transmit there through at least one electromagnetic radiation and forward the at least one electromagnetic radiation to at least one sample, and wherein the at least one fiber arrangement includes at least one first fiber which has at least one first filtering characteristic that filter the electromagnetic radiation; and
at least one receiving arrangement configured to receive the electromagnetic radiation that is filtered by at least one of the at least one first fiber or at least one second fiber which has the at least one second filtering characteristic that filter the at least one electromagnetic radiation.

14. The system according to claim 13, wherein the received at least one electromagnetic radiation is a Raman radiation associated with the at least one sample.

15. The system according to claim 13, wherein at least one portion of the at least one fiber arrangement is composed of or includes therein at least one of sapphire, diamond, clear graphite, Chalcogenide, borosilicate, zirconium fluoride, silver halide, a liquid core light guide, a gas core light guide, a hollow core waveguide, or a solid core photonic crystal fiber.

16. The system according to claim 13, wherein the at least one filtering characteristic is provided by a fiber Bragg grating.

17. The system according to claim 13, wherein at least one of the at least one first fiber or the at least one second fiber is filtered based on at least one of the at least one first filtering characteristic or the at least one second filtering characteristic to prevent at least one portion of the at least one electromagnetic radiation having particular wavelengths from being forwarded therein.

18. A system, comprising:
at least one first fiber arrangement including optical transmitting characteristics, configured to transmit there through at least one electromagnetic radiation and forward the at least one electromagnetic radiation to at least one sample; and
at least one second fiber arrangement configured to receive the electromagnetic radiation that is filtered and received from the at least one sample,
wherein the at least one electromagnetic radiation has at least one characteristic so as to at least one of reduce or substantially eliminate a fluorescence from the at least one sample.

19. The system according to claim 18, wherein the at least one electromagnetic radiation causes a stimulated depletion of the fluorescence from the at least one sample.

20. The system according to claim 18, wherein the at least one electromagnetic radiation photo-bleaches the fluorescence from the at least one sample.

21-41. (canceled)

42. A method, comprising:
transmitting through at least one fiber arrangement at least one electromagnetic radiation, the at least one fiber arrangement including optical transmitting characteristics;
forwarding the at least one electromagnetic radiation to at least one sample via the at least one fiber arrangement; wherein at least one portion of the at least one fiber arrangement is composed of or includes therein at least one of sapphire, diamond, clear graphite, Chalcogenide, borosilicate, zirconium fluoride, silver halide, a liquid core light guide, a gas core light guide, a hollow core waveguide, or a solid core photonic crystal fiber; and
receiving the electromagnetic radiation from the at least one sample and filtering the same using at least one receiving arrangement.
